(19) United States
(12) Patent Application Publication
(10) Pub. No.: US 2024/0373719 A1
(43) Pub. Date: Nov. 7, 2024

(54) DISPLAY DEVICE AND METHOD FOR MANUFACTURING THE SAME

(71) Applicant: Samsung Display Co., LTD., Yongin-si (KR)

(72) Inventors: WONBEOM LEE, Yongin-si (KR); JUNEHYOUNG PARK, Yongin-si (KR); JUNWOO YOU, Yongin-si (KR); SUK WON JUNG, Yongin-si (KR)

(21) Appl. No.: 18/598,548

(22) Filed: Mar. 7, 2024

(30) Foreign Application Priority Data
May 2, 2023 (KR) 10-2023-0057278

(51) Int. Cl. H10K 59/80; H10K 59/12

(52) U.S. Cl. CPC H10K 59/80; H10K 59/1201

(57) ABSTRACT

A display device includes a display panel including a first region, and a second region surrounding the first region, and a coating layer disposed under the display panel, and overlapping the first region and the second region. The coating layer includes a base layer including an organic material, and a plurality of fillers dispersed in the base layer, the coating layer has a viscosity of about 1000 cps or greater, a lower surface of the coating layer includes a first lower surface overlapping the first region, and a second lower surface overlapping the second region, and a surface roughness of the first lower surface is greater than a surface roughness of the second lower surface.

This application claims priority to Korean Patent Application No. 10-2023-0057278, filed on May 2, 2023, and all the benefits accruing therefrom under 35 U.S.C. § 119, the content of which in its entirety is herein incorporated by reference.

### BACKGROUND

### 1. Field

The disclosure herein relates to a display device and a method for manufacturing the display device, and more particularly, to a display device including a display panel with improved reliability and a method for manufacturing the display device.

### 2. Description of the Related Art

Various display devices used for a multimedia device such as a television, a mobile phone, a tablet computer, and a game console are being developed. A display device may include various functional layers to provide, to a user, a high-quality color image.

Recently, to perform a display device having various forms, such as a curved display device, a rollable display device, or a foldable display device, research on a thin display device is in progress. Such a thin display device may be achieved by reducing number of the functional layers, and including a functional layer having various functions.

### SUMMARY

When a thin display device is manufactured, the display device may be damaged by an impact generated during manufacture of the display device due to a thin thickness of the display device, and therefore the display may be desired to secure impact resistance. Accordingly, research on a structure of a display device having a thin thickness and improved impact resistance at the same time is in progress.

The disclosure provides a display device having improved reliability by disposing a single coating layer under a display panel, and a method for manufacturing the same.

An embodiment of the invention provides a display device including a display panel including a first region, and a second region surrounding the first region, and a coating layer disposed under the display panel, and overlapping the first region and the second region, where the coating layer includes a base layer including an organic material, and a plurality of fillers dispersed in the base layer, the coating layer has a viscosity of about 1000 centipoises (cps) or greater, a lower surface of the coating layer includes a first lower surface overlapping the first region, and a second lower surface overlapping the second region, and a surface roughness of the first lower surface is greater than a surface roughness of the second lower surface.

In an embodiment, the coating layer may be disposed directly on a lower surface of the display panel.

In an embodiment, the base layer may include a photocurable resin, and the plurality of fillers may each include a light-transmissive material.

In an embodiment, the plurality of fillers may have an average diameter in a range of about 1 micrometer (μm) to about 70 μm.

In an embodiment, the coating layer may have a thickness in a range of about 30 μm to about 300 μm.

In an embodiment, the display device may further include a circuit board electrically connected to the display panel, where the lower surface of the coating layer may be in contact with at least a portion of the circuit board.

In an embodiment, the display device may further include an electronic module disposed under the coating layer, where the display panel may include a signal transmission region, and a non-transmission region adjacent to the signal transmission region, and the electronic module may overlap the signal transmission region, and the coating layer may overlap the non-transmission region.

In an embodiment, the electronic module may be a sensor module or a camera module.

In an embodiment of the invention, a method for manufacturing a display device includes preparing a display panel including a first region, and a second region surrounding the first region, disposing a mold on a lower surface of the display panel in a way such that an internal space is provided between the display panel and the mold, supplying a preliminary coating material to the internal space, and forming a coating layer on the lower surface of the display panel by curing the preliminary coating material, wherein the preliminary coating material overlaps the first region and the second region, and includes a base resin and a plurality of fillers dispersed in the base resin.

In an embodiment, the mold may include a light-transmissive material, and the mold may include glass or a transparent plastic.

In an embodiment, an injection port may be defined through a region of the mold overlapping the first region, and the preliminary coating material may be injected into the internal space through the injection port.

In an embodiment, the mold may include a frame, and a functional layer disposed under the frame, and the functional layer may include fluorine.

In an embodiment, the functional layer may be directly disposed on a lower surface of the frame, and the functional layer may be composed of fluorine.

In an embodiment, a height of the internal space may be in a range about 30 μm to about 300 μm.

In an embodiment, the preliminary coating material may be supplied to entirely cover the lower surface of the display panel.

In an embodiment, the preliminary coating material may include a flat portion overlapping the second region, and a protrusion portion protruding from the flat portion in a direction being away from the display panel, and overlapping the first region.

In an embodiment, the forming the coating layer may include forming a first cured resin by curing the flat portion, and a second cured resin by curing the protrusion portion, and cutting at least a portion of the second cured resin.

In an embodiment, the forming the coating layer may include cutting all of the second cured resin.

In an embodiment, the forming the coating layer may include photo-curing the base resin by emitting light onto the mold.

### BRIEF DESCRIPTION OF THE DRAWINGS

The above and other features of the invention will become more apparent by describing in further detail embodiments thereof with reference to the accompanying drawings, in which:

FIG. 1 is a perspective view of a display device according to an embodiment of the invention;

FIG. 2 is an exploded perspective view of a display device according to an embodiment of the invention;

FIG. 3 is a cross-sectional view of display device according to an embodiment of the invention;

FIG. 4 is a cross-sectional view of a display panel according to an embodiment of the invention;

FIG. 5A is a cross-sectional view of a display module according to an embodiment of the invention;

FIG. 5B is a cross-sectional view of a display module and an electronic module according to an embodiment of the invention;

FIG. 6 is a flowchart illustrating a method for manufacturing a display device according to an embodiment of the invention;

FIG. 7 is a perspective view of a display module illustrating an operation in a method for manufacturing a display device according to an embodiment of the invention; and

FIGS. 8A to 8E are cross-sectional views illustrating operations in a method for manufacturing a display device according to an embodiment of the invention, respectively.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In this specification, when a component (or region, layer, portion, etc.) is referred to as “on”, “connected”, or “coupled” to another component, it means that it is placed/connected/coupled directly on the other component or a third component can be disposed between them.

It will be understood that when an element is referred to as being “on” another element, it can be directly on the other element or intervening elements may be present therebetween. In contrast, when an element is referred to as being “directly on” another element, there are no intervening elements present. For example, “directly disposed” may mean placing two layers or two members without using an additional member such as an adhesive member therebetween.

The same reference numerals or symbols refer to the same elements. In addition, in the drawings, thicknesses, ratios, and dimensions of components are exaggerated for effective description of technical content.

Terms such as first and second may be used to describe various components, but the components should not be limited by the terms. These terms are only used for the purpose of distinguishing one component from other components. For example, without departing from the scope of the invention, a first component may be referred to as a second component, and similarly, a second component may be referred to as a first component. Singular expressions include plural expressions unless the context clearly indicates otherwise.

In addition, terms such as “below”, “lower”, “above”, and “upper” are used to describe the relationship between components shown in the drawings. The terms are relative concepts and are described based on the directions indicated in the drawings.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used in this specification have the same meaning as commonly understood by one of ordinary skill in the art to which this invention belongs. In addition, terms such as terms defined in commonly used dictionaries should be interpreted as having a meaning consistent with the meaning having in the context of the related technology, and should not be interpreted as too ideal or too formal unless explicitly defined here.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

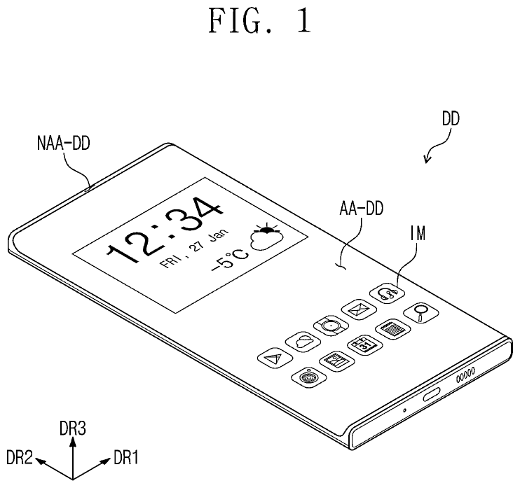

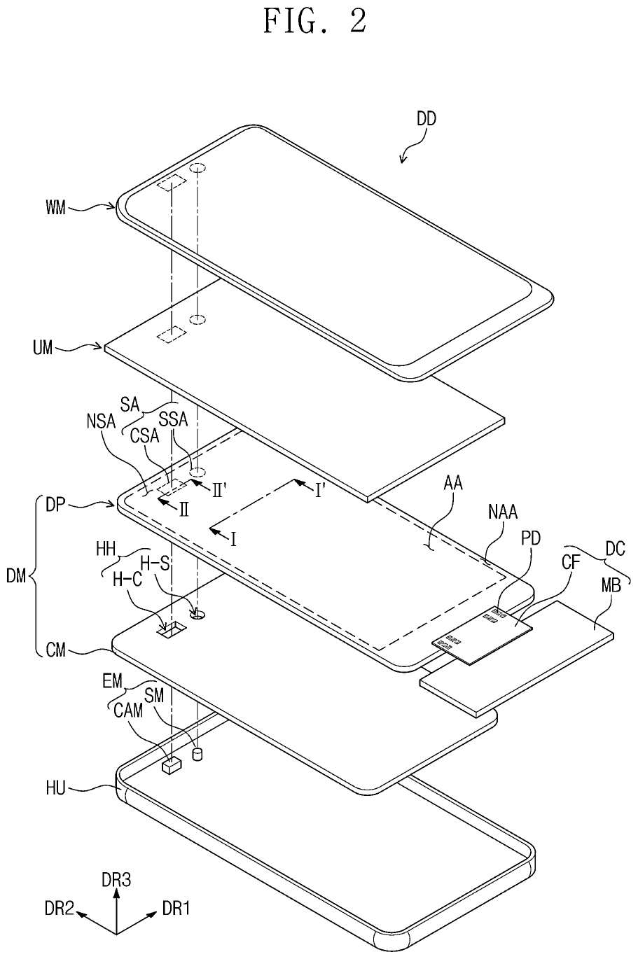

FIG. 1 is a perspective view of a display device DD according to an embodiment of the invention. FIG. 2 is an exploded perspective view of the display device DD according to an embodiment of the invention.

FIG. 1 illustrates an embodiment where the display device DD is a mobile phone. However, the display device DD is not limited thereto, and may be a small- or medium-sized display device such as a tablet computer, a car navigation system, a game console, a wearable device, or a camera.

The display device DD may display an image IM through an active region AA-DD. The active region AA-DD may include a flat surface defined by a first direction DR1 and a second direction DR2. The active region AA-DD may further include a curved surface bent from at least one side of the flat surface defined by the first direction DR1 and the second direction DR2. In an embodiment, as shown in FIG. 1, the display device DD may include two curved surfaces respectively bent from opposing side surfaces of the flat surface defined by the first direction DR1 and the second direction DR2. However, a shape of the active region AA-DD is not limited thereto. In an embodiment, for example, the active region AA-DD may include only a flat surface, and the active region AA-DD may further include at least two curved surfaces, for example, four curved surfaces respectively bent from four side surfaces of the flat surface.

In FIG. 1 and the following drawings, first to third directions DR1, DR2, and DR3 are illustrated, but directions indicated by the first to third directions DR1, DR2, and DR3 described in the disclosure are relative concepts, and may thus be changed to other directions.

In the disclosure, the first direction DR1 and the second direction DR2 may be orthogonal to each other, and the third direction DR3 may be a normal direction of the plane defined by the first direction DR1 and the second direction DR2. In the disclosure, the wording, “on a plane”, “in a plan view” or “when viewed in the third direction DR3” may mean “when seen on a plane defined by the first direction DR1 and the second direction DR2”, and the third direction DR3, which is the normal direction of the plane defined by the first direction DR1 and the second direction DR2, may be a thickness direction of the display device DD.

The display device DD may include the active region AA-DD and a peripheral region NAA-DD adjacent to the active region AA-DD. The active region AA-DD may correspond to a display region AA of a display panel DP to be described later, and the peripheral region NAA-DD may correspond to a non-display region NAA of the display panel DP.

The peripheral region NAA-DD may be a region blocking a light signal and disposed on an outer side of the active region AA-DD to surround the active region AA-DD. In an embodiment, the peripheral region NAA-DD may be disposed on a side surface, not on the front surface of the display device DD. In an embodiment, the peripheral region NAA-DD may be omitted.

In an embodiment, as shown in FIG. 2, the display device DD according to an embodiment may include a window WM, a housing HU, a display module DM, a circuit board DC, and an upper member UM.

The display device DD according to an embodiment may include the window WM disposed on the display panel DP. The window WM define an outer surface of the display device DD. Although not illustrated, the window WM may include a base substrate, and may further include functional layers such as an anti-reflective layer, an anti-fingerprint layer, an optical layer that controls a phase.

In the display device DD according to an embodiment, the upper member UM may be disposed under the window WM and on top of the display module DM. The upper member UM may include an anti-reflective layer and an input-sensing sensor. The anti-reflective layer lowers external light reflectance. The input-sensing sensor senses a user's external input. The upper member UM may further include an adhesive layer that bonds the anti-reflective layer and the input-sensing sensor to each other.

In the display device DD according to an embodiment, the display module DM may be disposed under the upper member UM. The display module DM may include the display panel DP and a coating layer CM.

The display panel DP may include (or be divided into) the display region AA on which the image IM is displayed, and the non-display region NAA adjacent to the display region AA. That is, the front surface of the display panel DP may include the display region AA and the non-display region NAA. The display region AA may be a region activated in response to an electrical signal.

The non-display region NAA may be adjacent to the display region AA. The non-display region NAA may surround the display region AA. A driving circuit or driving wires for driving the display region AA, various signal lines or pads for supplying the electrical signal to the display region AA, electronic elements, or the like may be disposed in the non-display region NAA.

The display region AA may include a signal transmission region SA and a non-transmission region NSA. The signal transmission region SA may be a region overlapping an electronic module EM, and the non-transmission region NSA may be a region disposed to surround at least a portion of the signal transmission region SA. The non-transmission region NSA may correspond to a region except for the signal transmission region SA in the display panel DP.

The electronic module EM may overlap the signal transmission region SA. The electronic module EM may receive an external input transferred through the signal transmission region SA, or may supply an output through the signal transmission region SA. The signal transmission region SA may include a camera-sensing region CSA and a sensor-sensing region SSA. Under the display panel DP, a camera module CAM may be disposed to overlap the camera-sensing region CSA, and a sensor module SM may be disposed to overlap the sensor-sensing region SSA. Although not illustrated, in an alternative embodiment, a predetermined opening may be defined in the signal transmission region SA of the display panel DP. Accordingly, one portion of the display panel DP may be penetrated.

FIG. 2 illustrates an embodiment where the signal transmission region SA includes the camera-sensing region CSA and the sensor-sensing region SSA, but the number of the signal transmission region SA is not limited thereto, and a single signal transmission region SA or three or more signal transmission regions SA may be defined in the display panel DP. FIG. 2 illustrates an embodiment where the shape of each of the signal transmission regions SA is a circle or a tetragon, but the shape of the signal transmission region SA is not limited thereto, and may be variously defined as needed.

On a plane or when viewed in the third direction DR3, the signal transmission region SA may have a smaller area than the non-transmission region NSA. The signal transmission region SA may have a (light) transmittance different from that of the non-transmission region NSA. The signal transmission region SA may have a greater transmittance than the non-transmission region NSA.

In the display panel DP according to an embodiment, some of the driving circuit, the driving wires, or the like for driving pixels (not shown) disposed in the signal transmission region SA may be disposed in a portion of the non-display region NAA, or the non-transmission region NSA. Accordingly, the signal transmission region SA may have a smaller wiring density than the non-transmission region NSA. However, an embodiment of the invention is not limited thereto, and the signal transmission region SA may substantially have a same wiring density as the non-transmission region NSA.

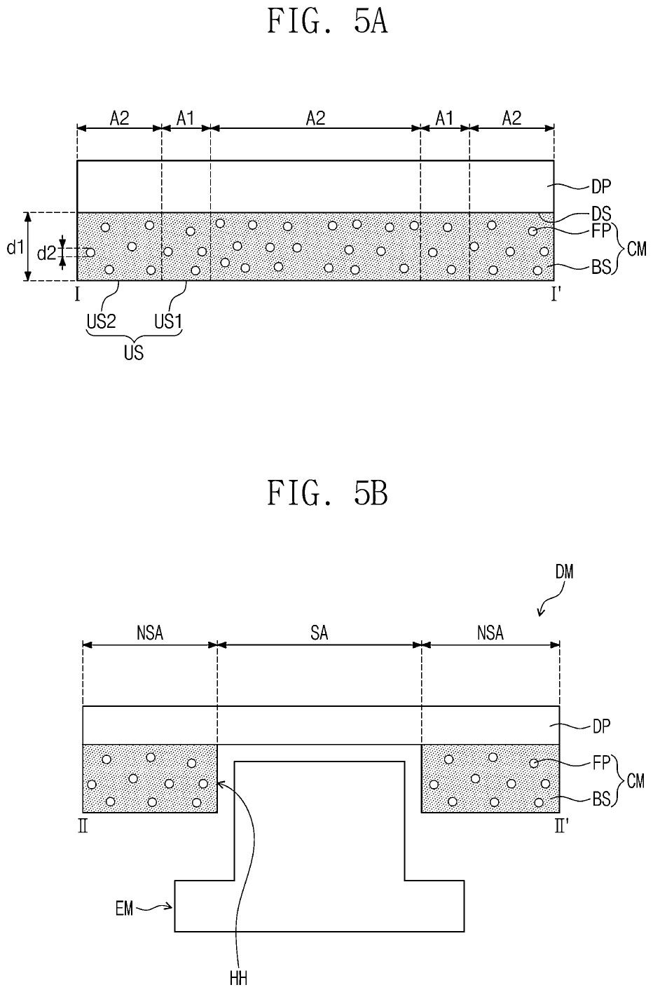

The display panel DP may include a light-emitting element layer DP-ED (see FIG. 4) including an organic light-emitting element, a quantum-dot light-emitting element, a micro-LED light-emitting element, a nano-LED light-emitting element, or the like. The light-emitting element layer DP-ED (see FIG. 4) may be a component that substantially generate images.

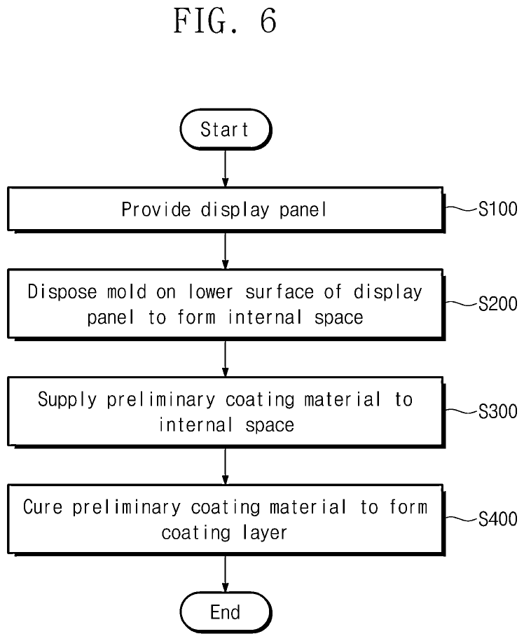

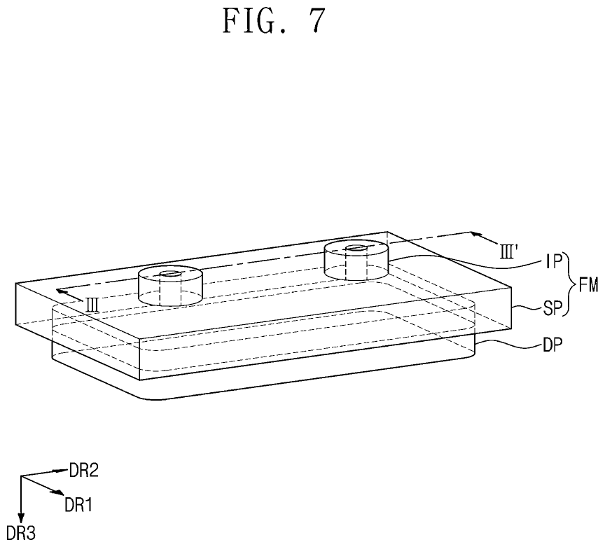

The coating layer CM may be disposed under the display panel DP. The coating layer CM may be a member that supports the display panel DP, and that performs a heat-dissipation function for emitting heat generated in the display panel DP. A hole HH may be defined in the coating layer CM. The hole HH may be defined in a region of the coating layer CM corresponding to the electronic module EM. The hole HH may be defined in the coating layer CM overlapping the signal transmission region SA. In an embodiment, the hole HH of the coating layer CM may be defined in singular or plural. The hole HH may include a sensor hole H-S and a camera hole H-C. The sensor hole H-S may correspond to the sensor-sensing region SSA described above, and the camera hole H-C may correspond to the camera-sensing region CSA described above. That is, under the coating layer CM, the sensor module SM may be disposed to overlap the sensor hole H-S, and the camera module CAM may be disposed to overlap the camera hole H-C. Detailed description for the coating layer CM will be made with reference to FIG. 5A and the following drawings.

The display device DD may include a circuit board DC connected to the display panel DP. The circuit board DC may include a flexible board CF and a main board MB. The flexible board CF may include an insulating film and conductive wires mounted on the insulating film. The conductive wires are connected to the pads PD to electrically connect the circuit board DC and the display panel DP. Alternatively, the flexible board CF may be omitted, and then the main board MB may be directly connected to the display panel DP.

The main board MB may include signal lines and electronic elements which are not illustrated. The electronic elements may be connected to the signal lines and electrically connected to the display panel DP. The electronic elements generate various electrical signals, for example, a signal for generating the image IM or a signal for sensing an external input, or processes a sensed signal, in an embodiment, the main board MB may be provided in plurality respectively corresponding to electrical signals for generating and processing, but an embodiment of the invention is not limited thereto.

In the display device DD according to an embodiment, the electronic module EM may be an electronic part that outputs or receives a light signal. In an embodiment, for example, the electronic module EM may include the camera module CAM and the sensor module SM. The camera module CAM may receive external light through the camera-sensing region CSA to capture an external image. In addition, the sensor module SM may be a sensor such as a proximity sensor or an infrared light-emitting sensor that outputs or receives the external light through the sensor-sensing region SSA.

The display device DD according to an embodiment may include the housing HU disposed under the coating layer CM. The display panel DP, or the like may be accommodated in the housing HU. In the display device DD according to an embodiment, the window WM and the housing HU may be coupled to constitute an exterior of the display device DD.

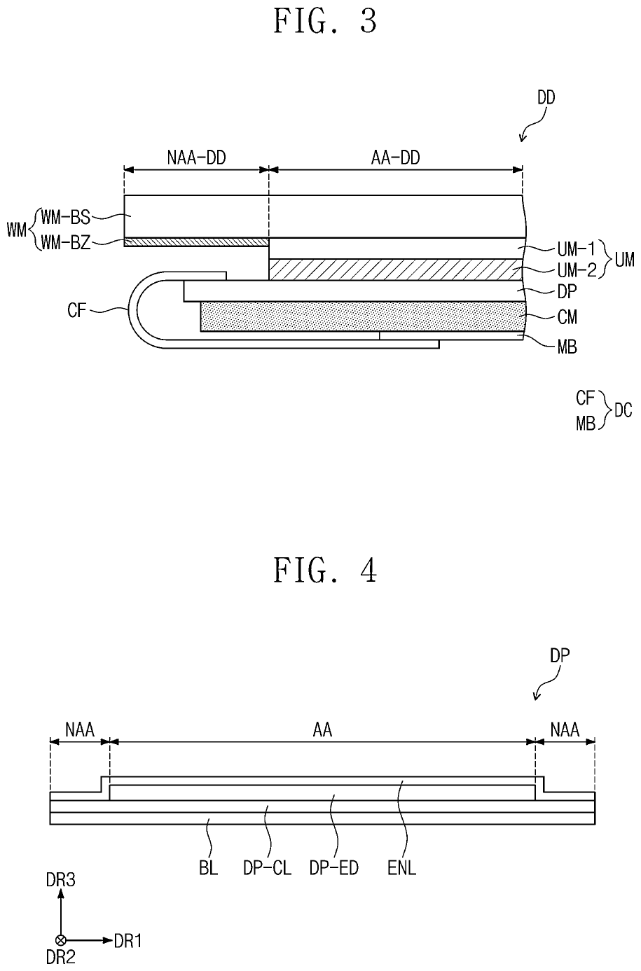

FIG. 3 is a cross-sectional view illustrating a partial configuration of a display device DD according to an embodiment of the invention.

Referring to FIG. 3, the display device DD according to an embodiment of the invention may include a window WM, an upper member UM, a display panel DP, a circuit board DC, and a coating layer CM.

In an embodiment, the window WM may cover the front surface of the display panel DP. The window WM may include a base substrate WM-BS and a bezel pattern WM-BZ. The base substrate WM-BS may include a first base layer that is transparent, such as a glass substrate or a transparent film. The bezel pattern WM-BZ may have a multi-layered structure. The multi-layered structure may include a color layer and a black light-blocking layer. The color layer and the black light-blocking layer may be formed through deposition, printing, and coating. Alternatively, the bezel pattern WM-BZ may be omitted from the window WM, and may be formed on the upper member UM, not on the base substrate WM-BS.

In an embodiment, the upper member UM includes an anti-reflective layer UM-1 and an input sensor UM-2.

The anti-reflective layer UM-1 may lower external light reflectance. The anti-reflective layer UM-1 may include a retarder and/or a polarizer. The anti-reflective layer UM-1 may include a polarizing film or color filters. The color filters may have a predetermined arrangement. The arrangement of the color filters may be determined in consideration of emission colors of pixels included in the display panel DP. The anti-reflective layer UM-1 may further include division layers adjacent to the color filters.

The input sensor UM-2 may include a plurality of sensing electrodes (not shown) for sensing an external input, trace lines (not shown) connected to the plurality of sensing electrodes, and an inorganic layer and/or an organic layer for insulating/protecting the plurality of sensing electrodes or the trace lines. The input sensor UM-2 may be a capacitive sensor, but is not specially limited thereto.

When the display panel DP is manufactured, the input sensor UM-2 may be formed, through a continuous process, directly on an encapsulation layer ENL (shown in FIG. 4) to be described later. However, an embodiment of the invention is not limited thereto, and the input sensor UM-2 may be manufactured as a separate panel from the display panel DP, and then may be attached to the display panel DP by an adhesive layer.

In an alternative embodiment, an adhesive layer may be further disposed between the window WM and the anti-reflective layer UM-1, and the adhesive layer may be further disposed between the anti-reflective layer UM-1 and the input sensor UM-2. The window WM, the anti-reflective layer UM-1, and the input sensor UM-2 may be respectively coupled to each other through the adhesive layers.

In an embodiment, the circuit board DC may include the flexible board CF and the main board MB. The flexible board CF according to an embodiment may be assembled in a bent state. Accordingly, the main board MB may be disposed on a rear surface of the display panel DP, and may be stably accommodated in a space supplied by the housing HU (see FIG. 2). In an embodiment, for example, the flexible board CF may be bent toward the rear surface of the display panel DP, and may be disposed under the lower member LM, but an embodiment of the invention is not limited thereto. In an alternative embodiment, the flexible board CF may be omitted, and in such an embodiment, the main board MB may be directly disposed under the coating layer CM, or may be mounted in the coating layer CM.

In an embodiment, the coating layer CM is disposed under the display panel DP. The coating layer CM may be directly disposed under the display panel DP to be in contact with a lower surface of the display panel DP. The coating layer CM may be in contact with the circuit board DC. In an embodiment, for example, the coating layer CM may be in contact with the main board MB. Detailed description for the coating layer CM will be made with reference to FIG. 5A and the following drawings.

FIG. 4 is a cross-sectional view of a display panel DP according to an embodiment.

The display panel DP according to an embodiment includes a base substrate BL, and a circuit layer DP-CL, a light-emitting element layer DP-ED, and an encapsulation layer ENL which are disposed on the base substrate BL. The base substrate BL may include a plastic substrate, a glass substrate, a metal substrate, an organic/inorganic composite material substrate or the like. In an embodiment, for example, the base substrate BL may include at least one polyimide layer.

The circuit layer DP-CL includes at least one insulating layer, semiconductor patterns, or conductive patterns. The insulating layer includes at least one inorganic layer and at least one organic layer. The semiconductor patterns and the conductive patterns may constitute signal lines, a pixel driving circuit, and a scan driving circuit. In addition, the circuit layer DP-CL may include a back metal layer.

The light-emitting element layer DP-ED includes a display element, for example, a light-emitting element. In an embodiment, for example, the light-emitting element may be an organic light-emitting element, a quantum-dot light-emitting element, a micro-LED light-emitting element, or a nano-LED light-emitting element. The light-emitting element layer DP-ED may further include an organic layer such as a pixel-defining film.

The light-emitting element layer DP-ED may be disposed in a display region AA. A non-display region NAA may be disposed in an outer periphery of the display region AA to surround the display region AA, and the light-emitting element may not be disposed in the non-display region NAA.

The encapsulation layer ENL may be disposed on the light-emitting element layer DP-ED to cover the light-emitting element layer DP-ED. The encapsulation layer ENL may be disposed on the circuit layer DP-CL to seal the light-emitting element layer DP-ED. The encapsulation layer ENL may be a thin-film encapsulation layer including a plurality of organic thin-films and inorganic thin-films. The encapsulation layer ENL may include a thin-film encapsulation layer having a stack structure of an inorganic layer/organic layer/inorganic layer. The stack structure of the encapsulation layer ENL is not specially limited thereto.

FIG. 5A is a cross-sectional view illustrating, in detail, a display module DM, which is a partial configuration of a display device. FIG. 5B is a cross-sectional view illustrating, in detail, a display module DM and an electronic module EM, which is a partial configuration of the display device. More particularly, FIG. 5A illustrates a cross-section taken along line I-I′ in FIG. 2, and FIG. 5B illustrates a cross-section taken along line II-II′ in FIG. 2.

Referring to FIG. 5A, the display module DM according to an embodiment of the invention may include a display panel DP and a coating layer CM disposed under the display panel DP. The display module DM may include or be composed of the display panel DP and the coating layer CM.

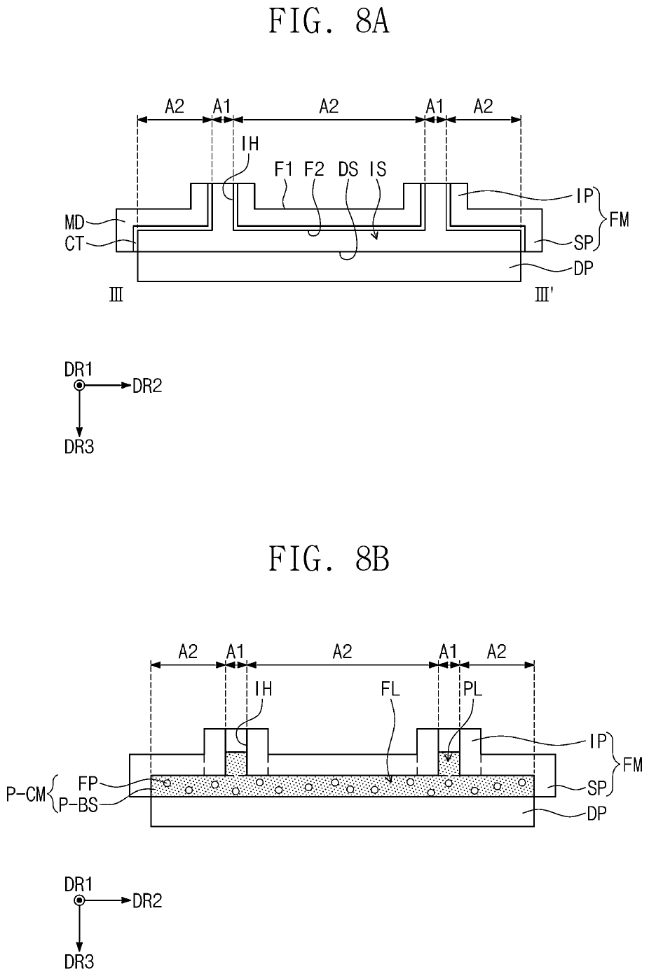

The display panel DP includes a first region A1 and a second region A2. The first region A1 may be defined as an arbitrary region in the display panel DP, and the second region A2 may surround the first region A1. The second region A2 may correspond to a region except for the first region A1 in the display panel DP. The first region A1 may be provided in plural. A length of each of the plurality of first regions A1 in the first direction DR1 may be in a range of about 100 micrometers (μm) to about 1000 μm. In an embodiment, for example, the length of each of the plurality of the first regions A1 in the first direction DR1 may be in a range of about 200 μm to about 400 μm. However, an embodiment of the invention is not limited thereto, and the first region A1 may be variously defined in the display panel DP according to a shape of a display device DD (see FIG. 1), a thickness of the coating layer CM, or the like. When the display device according to an embodiment of the invention is manufactured, the coating layer CM may be manufactured by injection molding, and in this case, the first region A1 may be defined as a region overlapping an injecting portion of a mold during the injection molding. Detailed description of a method for manufacturing the coating layer CM by the injection molding will be made with reference to FIG. 6 and the following drawings.

The coating layer CM is disposed under the display panel DP. The coating layer CM may be directly disposed under the display panel DP to be in contact with a lower surface DS of the display panel DP. In the display device according to an embodiment of the invention, only the coating layer CM may be disposed under the display panel DP. That is, the lowermost surface of the display module DM may be defined as a lower surface US of the coating layer CM. Accordingly, a thickness of the display device according to an embodiment may be reduced, and parts of the display device according to an embodiment may be simplified, thereby increasing process efficiency during manufacture of the display device according to an embodiment.

The coating layer CM overlaps the first region A1 and the second region A2. The lower surface US of the coating layer CM may include a first lower surface US1 overlapping the first region A1 and a second lower surface US2 overlapping the second region A2. A surface roughness of the first lower surface US1 is greater than a surface roughness of the second lower surface US2. Since a specific member is cut during manufacture of the coating layer CM according to an embodiment of the invention, a cutting mark may be included in the first lower surface US1. Accordingly, the surface roughness of the first lower surface US1 may be relatively greater than the surface roughness of the second lower surface US2.

A thickness d1 of the coating layer CM may be in a range of about 30 μm to about 300 μm. The thickness d1 of the coating layer CM overlapping the first region A1 and the thickness d1 of the coating layer CM overlapping the second region A2 may be substantially the same as each other. A viscosity of the coating layer CM may be A viscosity of the coating layer CM may be about 1000 centipoises (cps) or greater, e.g., in a range of about 1000 cps and about 100,000 cps. In an embodiment, for example, the viscosity of the coating layer CM may be in a range of about 10,000 cps to about 20,000 cps. Accordingly, the coating layer CM may support the display panel DP, etc., in the display device.

The coating layer CM includes a base layer BS and a plurality of fillers FP dispersed in the base layer BS. The coating layer CM may be a single layer including or composed of the base layer BS and the plurality of fillers FP. The plurality of fillers FP may be fillers dispersed in the base layer BS.

Since the coating layer CM includes the base layer BS and the plurality of fillers FP, the coating layer CM may perform multiple functions in the display device DD (see FIG. 1). In an embodiment, for example, the coating layer CM may support the display panel DP. The coating layer CM may protect the display panel DP, etc., from a physical impact applied from the outside of the display device DD (see FIG. 1). The coating layer CM may perform a heat-dissipation function for emitting heat generated by the display panel DP, or the like. The coating layer CM may have a function for blocking electromagnetic waves, or the like. However, the function of the coating layer CM is not limited thereto, and the coating layer CM may further perform other functions in the display device DD according to the characteristics, such as a thickness and a material, of the coating layer CM.

The base layer BS may supply a base material in which the plurality of fillers FP are dispersed. The base layer BS may include an organic material. The base layer BS may include (or be formed by using) at least one selected from an acrylic-based polymer, a urethane-based polymer, a silicone-based polymer, and an imide-based polymer. The base layer BS may include a curable resin. In an embodiment, for example, the base layer BS may include a photocurable resin. The base layer BS may include a material having a predetermined strength.

The plurality of fillers FP may each include an organic material or an inorganic material. In an embodiment, for example, the plurality of fillers FP may each include graphite or metal particles. The plurality of fillers FP may include a same material as each other, or include different materials from each other. The plurality of fillers FP may perform a same function as each other, or perform different functions from each other. Accordingly, the coating layer CM may perform a plurality of functions such as supporting, heat-dissipation, or blocking of the display device.

The plurality of fillers FP may each include a light-transmissive material. In an embodiment where the base layer BS includes the photocurable resin and the filler FP includes the light-transmissive material, the coating layer CM may be formed through photo-curing.

An average diameter d2 of the plurality of fillers FP may be in a range of about 1 μm about 70 μm. In an embodiment, for example, the average diameter d2 of the plurality of fillers FP may be in a range of about 10 μm to about 50 μm. FIG. 5A illustrates an embodiment where the fillers FP have a same diameters as each other, but an embodiment of the invention is not limited thereto, and the fillers FP may have a size distribution which is a substantially monodispersed distribution, or have a size distribution which is a polydispersed distribution obtained by mixing a plurality of particles having a monodispersed distribution.

The plurality of fillers FP may have a content in a range of about 30 weight percent (wt %) to about 80 wt % with respect to the total content of the whole materials included in the coating layer CM. In an embodiment, for example, the plurality of fillers FP may have a content in a range of about 50 wt % to about 80 wt % with respect to the total content of the whole materials included in the coating layer CM.

Referring to FIG. 5B, the display panel DP according to an embodiment of the invention may include a signal transmission region SA and a non-transmission region NSA. The coating layer CM according to an embodiment of the invention may overlap the non-transmission region NSA, and may not overlap the signal transmission region SA. Accordingly, the signal transmission region SA may have a greater transmittance than the non-transmission region NSA.

A hole HH may be defined in the signal transmission region SA in which the coating layer CM is not disposed. The hole HH may overlap the electronic module EM. At least a portion of the electronic module EM may be disposed inserted into the hole HH. In an embodiment, for example, the electronic module EM may be a camera module including a lens adjacent to the display panel DP. In an embodiment, the lens of the camera module may be disposed inserted into the hole HH. FIG. 5B illustrates an embodiment where the hole HH is defined only in the coating layer CM, but an embodiment of the invention in not limited thereto, and a predetermined opening may be further defined in the display panel DP as needed. Alternatively, a portion of the plurality of holes HH may be defined in the coating layer CM, and the other portion may be defined in both the coating layer CM and the display panel DP.

Hereinafter, a method for manufacturing a display device according to an embodiment will be described with reference to the drawings. Hereinafter, any repetitive detailed description of the same or like elements as those of the display device described with reference to FIGS. 1 to 5B will be omitted or simplified, and the following description will be focused on the features of the method for manufacturing a display device.

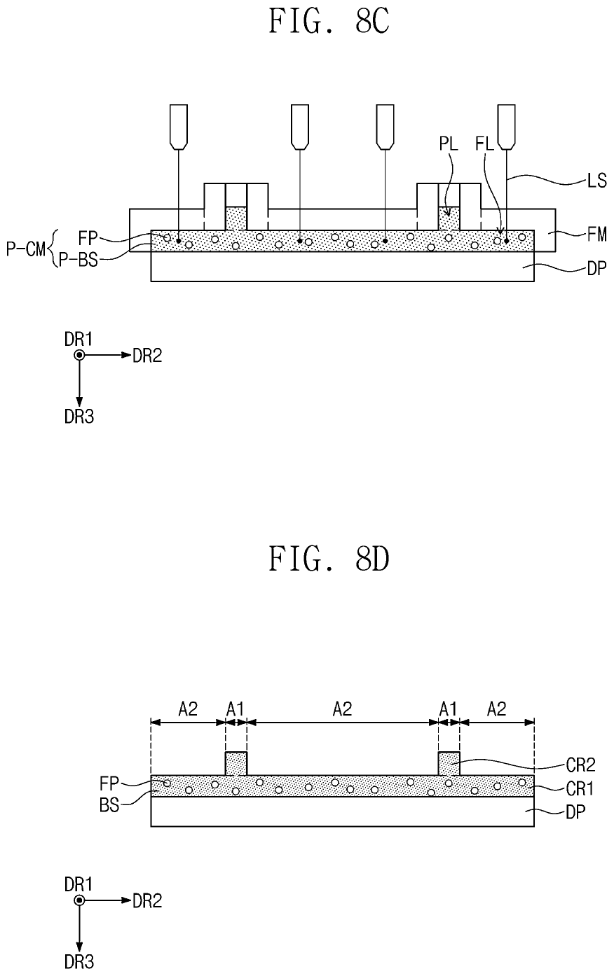

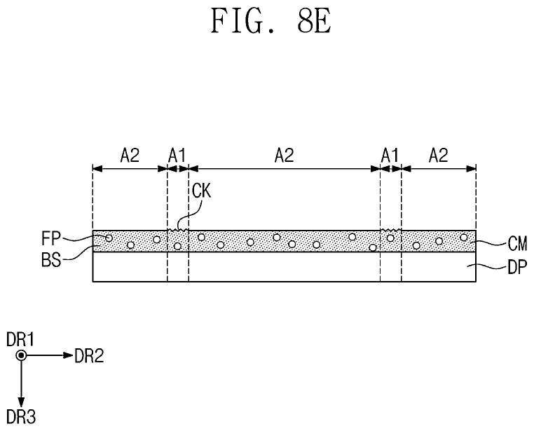

FIG. 6 is a flowchart illustrating a method for manufacturing a display device according to an embodiment of the invention. FIG. 7 is a perspective view of an operation in the method for manufacturing a display device according to an embodiment of the invention. FIGS. 8A to 8D are cross-sectional views of operations in the method for manufacturing a display device according to an embodiment of the invention. More particularly, FIG. 8A illustrates a cross-section taken along line III-III′ in FIG. 7.

Referring to FIG. 6, the method for manufacturing a display device according to an embodiment of the invention may include an operation (S100) of providing (or preparing) a display panel, an operation (S200) of disposing a mold on a lower surface of the display panel to form an internal space (or with an internal space therebetween), an operation (S300) of supplying a preliminary coating material to the internal space, and an operation (S400) of curing the preliminary coating material to form a coating layer.

Referring to FIGS. 7 and 8A, the method for manufacturing a display device according to an embodiment of the invention may include the operation of providing a display panel DP, and the operation of disposing a mold FM on a lower surface DS of the display panel DP. FIGS. 7 to 8E illustrate that the lower surface DS of the display panel DP is disposed on top of the display panel DP, for convenience of description of the method for manufacturing a display device according to an embodiment of the invention.

As the mold FM is disposed on the lower surface DS of the display panel DP, an internal space IS may be defined or formed between the display panel DP and the mold FM. A height of the internal space IS may be in a range of about 30 μm to about 300 μm. In the disclosure, the height of the internal space IS may mean a shortest vertical distance between the display panel DP and the mold FM when disposing the mold FM on the lower surface DS of the display panel DP.

The mold FM may include an injection portion IP and a shaping portion SP. The injection portion IP may be a path through which a preliminary coating material P-CM (see FIG. 8B) to be described later is injected into the internal space IS. An injection port IH overlapping a first region A1 may be defined in the injection portion IP. The injection port IH may correspond to an opening defined through a portion of the mold FM overlapping the first region A1. In the disclosure, the injection port IH may substantially define the first region A1, or a portion overlapping the injection port IH may be defined as the first region A1.

The shaping portion SP may overlap a second region A2. The shaping portion SP may include a first surface F1 adjacent to the lower surface DS of the display panel DP and a second surface F2 facing the first surface F1. A coating layer CM (see FIG. 5A) according to an embodiment of the invention may have a predetermined shape, and the shaping portion SP may be a mold for achieving a shape of the coating layer CM (see FIG. 5A). That is, the shortest vertical distance between the second surface F2 of the shaping portion SP and the display panel DP may be substantially the same as a thickness of the coating layer CM (see FIG. 5A), and the second surface F2 of the shaping portion SP may correspond to the lower surface US (see FIG. 5A) of the coating layer CM (see FIG. 5A).

The mold FM may include a frame MD and a functional layer CT disposed under the frame MD. In an embodiment, the functional layer CT may include fluorine. The functional layer CT may be a fluorine-coating layer composed of fluorine. The functional layer CT may be a fluorine-coating layer directly disposed on a lower surface of the frame MD. In such an embodiment where the functional layer CT includes fluorine, a preliminary coating material P-CM (see FIG. 8B) to be described later and the mold FM may not be in contact with each other although the preliminary coating material P-CM (see FIG. 8B) is injected into the internal space IS.

For convenience of illustration, FIGS. 7 and 8A illustrate only the mold FM and the display panel DP, but the method for manufacturing a display device according to an embodiment of the invention is not limited thereto. When the mold FM is disposed on the lower surface DS of the display panel DP, an upper member UM may be coupled to the display panel DP, or the upper member UM and the window WM may be coupled to the display panel DP.

Referring to FIG. 8B, the method for manufacturing a display device according to an embodiment of the invention may include an operation of supplying the preliminary coating material P-CM to the internal space IS defined between the display panel DP and the mold FM. That is, the preliminary coating material P-CM may be injected between the display panel DP and the mold FM.

The preliminary coating material P-CM may include a base resin P-BS and a plurality of fillers FP dispersed in the base resin P-BS. The base resin P-BS may include at least one selected from an acrylic polymer, a urethane-based polymer, a silicone-based polymer, and an imide-based polymer. The base resin P-BS may be supplied in a liquid state, and thus the preliminary coating material P-CM including the base resin P-BS may be injected into the internal space IS.

The preliminary coating material P-CM may be supplied to overlap the first region A1 and the second region A2. The preliminary coating material P-CM may be supplied to the entire lower surface US of the display panel DP to completely fill the internal space IS. The preliminary coating material P-CM may include a flat portion FL overlapping the second region A2 and a protrusion portion PL overlapping the first region A1. The flat portion FL may be defined as a portion filled between the shaping portion SP of the mold FM and the display panel DP, and the protrusion portion PL may be defined as a portion filled in the injection port IH. The protrusion portion PL may protrude from the flat portion FL in a direction being away from the display panel DP in the third direction DR3.

Referring to FIG. 8C, the method for manufacturing a display device according to an embodiment of the invention may include the operation of curing the preliminary coating material P-CM.

The operation of curing the preliminary coating material P-CM may include an operation of emitting light LS onto the mold FM. In an embodiment, for example, the emitted light LS may be ultraviolet rays. The mold FM may include a light-transmissive material. Accordingly, even when the light LS is emitted onto the mold FM, the emitted light LS may pass through the mold FM and reach the preliminary coating material P-CM. in an embodiment, for example, the mold FM may include glass. Alternatively, the mold FM may include transparent plastic. In an embodiment where the mold FM includes plastic, a glass transition temperature of the mold FM may be higher than a glass transition temperature of the preliminary coating material P-CM. Accordingly, although the light LS is emitted onto the mold FM, the mold FM may maintain a shape thereof without phase transition.

The preliminary coating material P-CM may include the base resin P-BS, and the base resin P-BS may include a curable resin. In an embodiment, for example, the base resin P-BS may include a photocurable resin. The preliminary coating material P-CM may include a plurality of fillers FP, and the plurality of fillers FP may each include a light-transmissive material. Accordingly, although the plurality of fillers FP are dispersed in the base resin P-BS, the light LS may entirely reach the base resin P-BS to completely cure the preliminary coating material P-CM.

FIG. 8C illustrates an embodiment where the light LS is emitted onto the preliminary coating material P-CM from thereabove, but an embodiment of the invention is not limited thereto, and a light lamp (not shown) corresponding to a light source of the light LS may be directly disposed on the mold FM.

Referring to FIGS. 8C and 8D, the operation of curing the preliminary coating material P-CM may include an operation of forming a first cured resin CR1 by curing the flat portion FL, and an operation of forming a second cured resin CR2 by curing the protrusion portion PL. The operation of forming the first cured resin CR1 and the operation of forming the second cured resin CR2 may be simultaneously performed in a same process.

The method for manufacturing a display device according to an embodiment of the invention includes an operation of separating the mold FM and the display panel DP from each other, after the operation of forming the first cured resin CR1 and the second cured resin CR2. Since the mold FM includes the functional layer CT (see FIG. 8A) including fluorine, the first or second cured resins CR1 or CR2 and the mold FM may not be in contact with each other. Accordingly, although the mold FM and the display panel DP are separated from each other, the first or second cured resin CR1 or CR2 may not remain in the mold FM.

Referring to FIGS. 8D and 8E, the method for manufacturing a display device according to an embodiment of the invention may include an operation of removing at least a portion of the second cured resin CR2. In an embodiment, for example, the second cured resin CR2 may be entirely cut by a cutting device (not shown). Since the second cured resin CR2 is cut, the coating layer CM may be formed. The coating layer CM may include the first cured resin CR1, and may include a cutting mark CK remaining after cutting the second cured resin CR2. Accordingly, a first lower surface US1 (see FIG. 5A) overlapping the first region A1 in the coating layer CM according to an embodiment of the invention may include the cutting mark CK, and a second lower surface US2 (see FIG. 5A) overlapping the second region A2 may not include the cutting mark CK. Therefore, the first lower surface US1 including the cutting mark CK may have a relatively greater surface roughness than the second lower surface US2 (see FIG. 5A) not including the cutting mark CK.

A display device according to an embodiment of the invention may include, under a display panel, a single coating layer that performs multiple functions, thereby reducing a thickness of the display device and simplifying parts thereof. In a conventional display device, where a display panel includes a light-emitting element, a plurality of members, such as a blocking layer, a heat-dissipation layer, a cushion layer, and a support layer, is typically provided under the display panel. In the display device according to the invention, a coating layer including a plurality of fillers that perform the above-described functions is disposed under a display panel, such that the functions performed by a conventional plurality of layers under a display panel may also be performed, and simultaneously effects of reducing a thickness, simplifying parts, and improving manufacturing process efficiency are attained. If such a coating layer is manufactured through typical technology such as inkjet printing, slit coating, or screen coating, there are limitations in that it is difficult to achieve a favorable thickness and viscosity of the coating layer, and to inject the plurality of fillers. However, since the method for manufacturing a display device according to an embodiment of the invention is manufactured through a molding technique by injecting the coating layer, it is possible to achieve a coating layer having even a specific thickness or specific shape. Specifically, since the method for manufacturing a display device according to an embodiment of the invention uses a mold corresponding to the coating layer, and injects a coating material between the display panel and the mold, the coating layer, although containing a plurality of fillers, may inject the plurality of fillers, and the coating layer, although having a predetermined thickness or greater, may have a uniform thickness. In addition, even when an edge of the coating layer has a curved shape along corners of the display panel, or the coating layer is not disposed in a predetermined region to sense a signal by a camera module, or the like, the coating layer may be manufactured by the method for manufacturing a display device according to an embodiment of the invention.

A display device according to the invention may include a coating layer under a display panel, and thus have an effect of reducing a thickness of the display device through replacing a plurality of functional members with the coating layer.

A method for manufacturing a display device according to the invention may form a coating layer under a display panel by using a mold, and thus form the coating layer having even various physical characteristics, thereby improving reliability.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display panel including a first region, and a second region surrounding the first region; and
a coating layer disposed under the display panel, and overlapping the first region and the second region,
wherein the coating layer includes a base layer including an organic material, and a plurality of fillers dispersed in the base layer,
the coating layer has a viscosity of about 1000 cps or greater,
a lower surface of the coating layer includes a first lower surface overlapping the first region, and a second lower surface overlapping the second region, and
a surface roughness of the first lower surface is greater than a surface roughness of the second lower surface.

2. The display device of claim 1, wherein the coating layer is disposed directly on a lower surface of the display panel.

3. The display device of claim 1, wherein the base layer comprises a photocurable resin.

4. The display device of claim 1, wherein the plurality of fillers each comprise a light-transmissive material.

5. The display device of claim 1, wherein the plurality of fillers have an average diameter in a range of about 1 μm to about 70 μm.

6. The display device of claim 1, wherein the coating layer has a thickness in a range of about 30 μm to about 300 μm.

7. The display device of claim 1, further comprising:
a circuit board electrically connected to the display panel,
wherein the lower surface of the coating layer is in contact with at least a portion of the circuit board.

8. The display device of claim 1, further comprising:
an electronic module disposed under the coating layer,
wherein the display panel includes a signal transmission region, and a non-transmission region adjacent to the signal transmission region, and
the electronic module overlaps the signal transmission region, and the coating layer overlaps the non-transmission region.

9. The display device of claim 8, wherein the electronic module is a sensor module or a camera module.

10. A method for manufacturing a display device, the method comprising:
preparing a display panel including a first region, and a second region surrounding the first region;
disposing a mold on a lower surface of the display panel in a way such that an internal space is provided between the display panel and the mold;
supplying a preliminary coating material to the internal space; and
forming a coating layer on the lower surface of the display panel by curing the preliminary coating material,
wherein the preliminary coating material overlaps the first region and the second region, and includes a base resin and a plurality of fillers dispersed in the base resin.

11. The method of claim 10, wherein the mold comprises a light-transmissive material.

12. The method of claim 10, wherein the mold comprises glass or a transparent plastic.

13. The method of claim 10, wherein an injection port is defined through a region of the mold overlapping the first region, and
the preliminary coating material is injected into the internal space through the injection port.

14. The method of claim 10, wherein the mold comprises a frame, and a functional layer disposed under the frame, and
the functional layer comprises fluorine.

15. The method of claim 10, wherein a height of the internal space is in a range of about 30 μm to about 300 μm.

16. The method of claim 10, wherein the preliminary coating material is supplied to entirely cover the lower surface of the display panel.

17. The method of claim 10, wherein the preliminary coating material comprises:
a flat portion overlapping the second region; and
a protrusion portion protruding from the flat portion in a direction being away from the display panel, and overlapping the first region.

18. The method of claim 17, wherein the forming the coating layer comprises:
forming a first cured resin by curing the flat portion, and a second cured resin by curing the protrusion portion; and
cutting at least a portion of the second cured resin.

19. The method of claim 18, wherein the forming the coating layer comprises cutting all of the second cured resin.

20. The method of claim 10, wherein the forming the coating layer comprises photo-curing the base resin by emitting light onto the mold.
